(19) United States
(12) Patent Application Publication
(10) Pub. No.: US 2010/0075495 A1
(43) Pub. Date: Mar. 25, 2010

(54) Method Of Selectively Plating Without Plating Lines

(76) Inventors: Chien-Wei Chang, Taoyuan (TW); Ting-Hao Lin, Taipei (TW); Yu-Te Lu, Taoyuan (TW)

Correspondence Address: LIN & ASSOCIATES INTELLECTUAL PROPERTY, INC., P.O. BOX 2339, SARATOGA, CA, 95070-0339, US

(21) Appl. No.: 12/237,402

(22) Filed: Sep. 25, 2008

(51) Int. Cl. H01L 21/44

(52) U.S. Cl. 438/652; 257/E21.476

(57) ABSTRACT

A method of selectively plating without plating lines is provided. The method employs a loading plate having a metalized temporary conductive layer. The loading plate and the temporary conductive layer are adapted for transmitting a plating current. A patterning photoresist layer is accorded for selectively and sequentially plating a separating metal layer, a plating protection layer, and a connection pad layer on to the temporary conductive layer. Then, the loading plate is further used for supplying current to form other circuit layers by a pressing lamination process. And when the plate process is completed or it is not need to plate, the loading plate and the temporary conductive layer can be removed, for further completing for example the solder mask process, and thus achieving the objective of plating without plating lines.

### BACKGROUND OF THE INVENTION

1. Field of the Invention

The present invention generally relates to a method of plating without plating lines, and more particularly, to a method of selectively plating without plating lines.

2. The Prior Arts

Nowadays, electronic products are fast developed with the trend toward lightness, slimness, and multifunction. Correspondingly, this demands greater I/O numbers for the chips of the electronic products. Currently, the flip-chip technology has been used in packaging many high class electronic products, and therefore the packaging densities thereof have also been increased correspondingly.

In order to satisfy the demand for high density carrier boards having a finer line space, layout spaces should be reserved as more as possible. For example, those conducting lines that are employed for the plating process, but become useless after the plating process, are often considered to be saved. Specifically, when plating a nickel gold (Ni/Au) layer onto a circuit layer of the package carrier board, in order to supply current for plating to the carrier board, specifically to the circuit layer to be electroplated, a conducting line is often used in connection with the circuit layer. Although, the circuit layer can be entirely covered by a plating Ni/Au layer by employing such a conducting line, after the plating process, the conducting line resides inside the carrier board, and disadvantageously occupies the valuable layout space. However, when conducting line having a reduced width is employed for the purpose of saving the layout space, the plating Ni/Au layer may be produced with an uneven thickness. Therefore, the plating lines having a reduced width are not a good solution for improving the layout density.

Recently, plating without the plating lines has been proposed by many manufacturers for improving the layout density. However, according to the conventional technologies, when neglecting the conducting line, the circuit layer cannot be entirely covered by the Ni/Au layer. In other words, only the upper side of the circuit layer can be covered, while the lateral side of the circuit layer cannot be covered.

Conventional technologies of plating without the plating lines include non-plating line (NPL), bottom plating, FBG gold pattern plating (GPP), Selective Gold Plating, electroless nickel and immersion gold (ENAG). However, all of these conventional technologies have disadvantages.

The NPL technology provides a method for plating a Ni/Au layer on an electrical connection pad of a substrate without the need of the laying out plating lines on the substrate. The electrical connection pads on the substrate are electrically connected with each other through the conductive film which covers the surface of the substrate and serves as an electrically conductive path. NPL provides a solution to solve the problem of insufficient circuit layout area due to the disposition of the plating lines.

However, NPL and bottom plating technologies have similar disadvantages. If the layout pattern includes independent nets which are disposed in a same layer, the manufacturing process may become too complicated to execute. In other words, difficulties or failures may be raised when the nets are not connected to another side, e.g., a ball pad, or an inner layer power and ground, by a conducting through hole or a via.

GPP technology is featured in providing a process other than NPL. GPP technology provides an IC carrier board design for plating a Ni/Au layer on an electrical connection pad of a substrate without the need of the laying out plating lines on the substrate. However the GPP process electroplates Ni/Au onto the entirety of the circuit, the overall cost of materials is very high. Moreover, because the circuit layer is entirely covered with the Ni/Au layer, the adhesion performance between solder mask and the gold is weaker than that between solder mask and copper.

A disadvantage of the selective gold plating technology is that it has a narrow operating window, and therefore permeable plating may happen when the plating the Ni/Au layer, which can decrease the yield. As to the ENAG technology, it has the drawbacks such as that the chemical solution is not easily controlled, the chemical solution sometimes may attack the solder mask, as well as the problems, including black pad, thin edge-effect, and skip-plate may happen. Moreover, the black pad can cause poor bondability between the solder balls and the pads so that the solder balls may fall off.

In addition to all of the aforementioned technologies, it is also proposed to provide a temporary plating line, which is adapted for avoiding all of the above-mentioned drawbacks, and is further adapted for realizing a high density carrier board by complying with a removable conductivity.

Taiwan patent No. I262750 discloses “Process for Electroplating Metal Layer without Plating Lines after the Solder Mask Process”, and Taiwan patent No. I240400 discloses “Method for Fabricating a Packaging Substrate”. Both of the prior arts employ a method for plating without plating lines. According to the method for plating without plating lines, a plating current is supplied from an opposite side of the carrier board via a plating metal on a core through hole to a solder pad to be electroplated. The temporary plating line is removed upon the completeness of the plating process. However, this method is specifically adapted for plating a certain portion of the entire metal layer, and configuring a protection layer with respect to this certain portion. This method is not applicable when plating an independent solder pad, which is not connected to any metal portion of the carrier board.

### SUMMARY OF THE INVENTION

A primary objective of the present invention is to provide a method of selectively plating without plating lines. The method employs a reverse process which plates Au/Ni first and then plates copper (Cu) to form a protection layer, a connection pad layer, and performing an Cu/Ni etching process after completing lamination and transfer process, for removing a temporary conductive layer, a separating metal layer, and finally exposing a gold-plated protection layer. The method of the present invention differs from the conventional technologies, which require for plating gold to the protection layer at final. When executing the method, a detachable loading plate and the temporary conductive layer are adapted to provide a large range of plating current, so that even an independent pad which is not connected to any metal portion of the carrier board can also be used. The loading plate and the temporary conductive layer can be removed when the plate process is completed or it is not need to plate, thus achieving the objective of plating without plating lines.

For achieving the foregoing objective of the present invention, the present invention provides a method of selectively plating without plating lines. The method employs a loading plate having a metalized temporary conductive layer. The loading plate and the temporary conductive layer are adapted for transmitting a plating current. A patterning photoresist layer is accorded for selectively and sequentially plating a separating metal layer, a plating protection layer, and a connection pad layer on to the temporary conductive layer. Then, the loading plate is further used for supplying current to form other circuit layers by a pressing lamination process. And when the plate process is completed or it is not need to plate, the loading plate and the temporary conductive layer can be removed, for further completing for example the solder mask process, and thus achieving the objective of plating without plating lines.

### BRIEF DESCRIPTION OF THE DRAWINGS

The present invention will be apparent to those skilled in the art by reading the following detailed description of a preferred embodiment thereof, with reference to the attached drawings, in which:

FIGS. 1A through 1J are schematic diagrams illustrating a method of selectively plating without plating lines according to a first embodiment of the present invention; and

FIGS. 2A through 2G are schematic diagrams illustrating a method of selectively plating without plating lines according to a second embodiment of the present invention.

### DETAILED DESCRIPTION OF THE PREFERRED EMBODIMENT

The accompanying drawings are included to provide a further understanding of the invention, and are incorporated in and constitute a part of this specification. The drawings illustrate embodiments of the invention and, together with the description, serve to explain the principles of the invention.

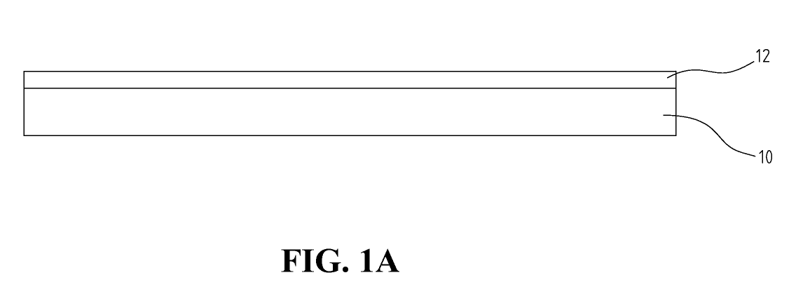

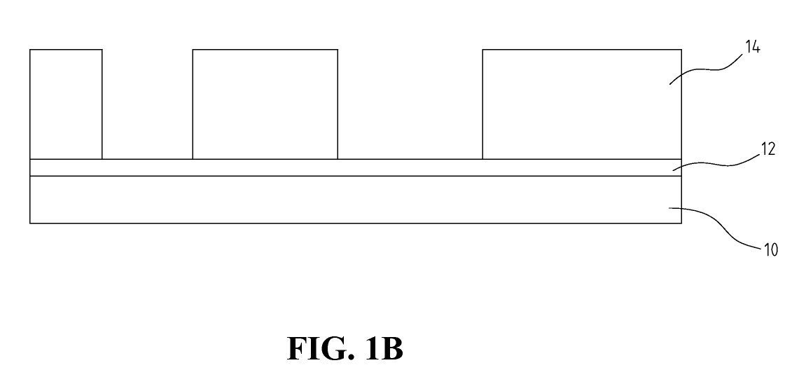

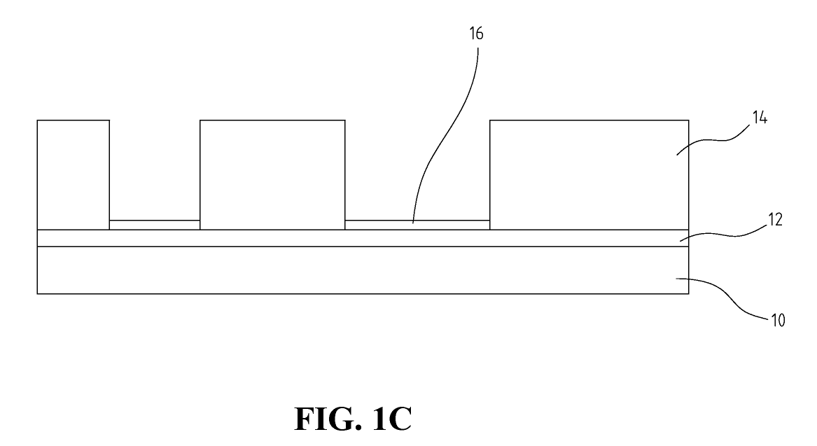

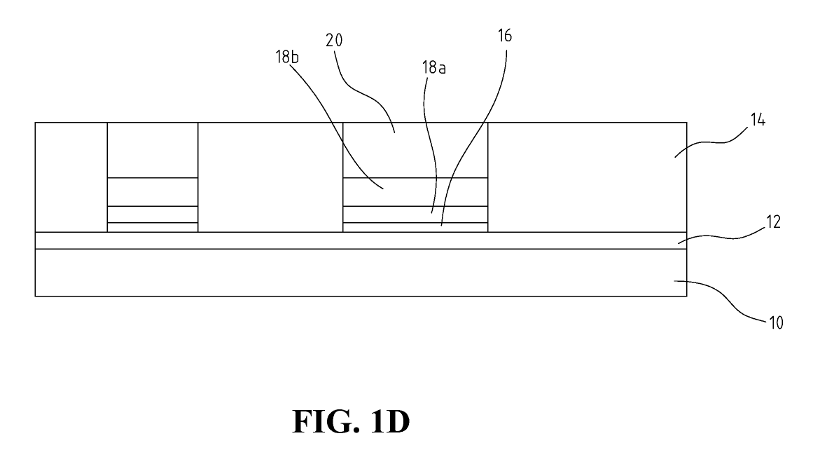

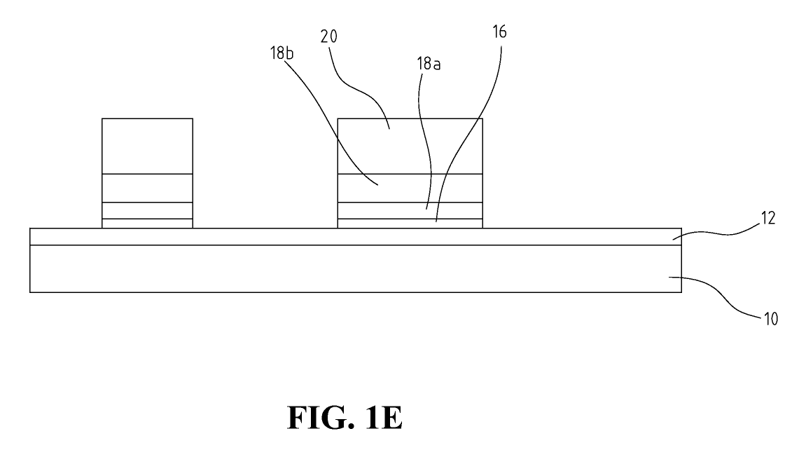

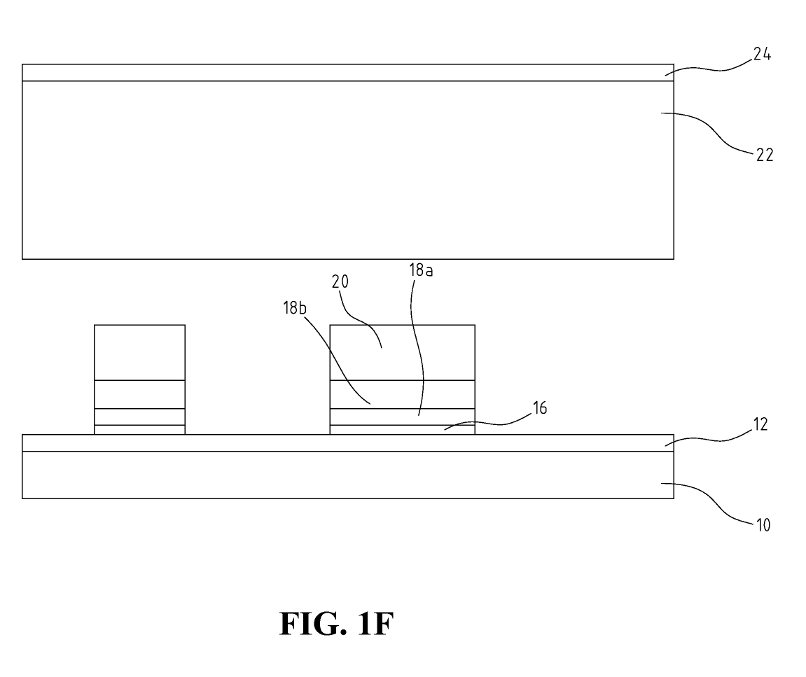

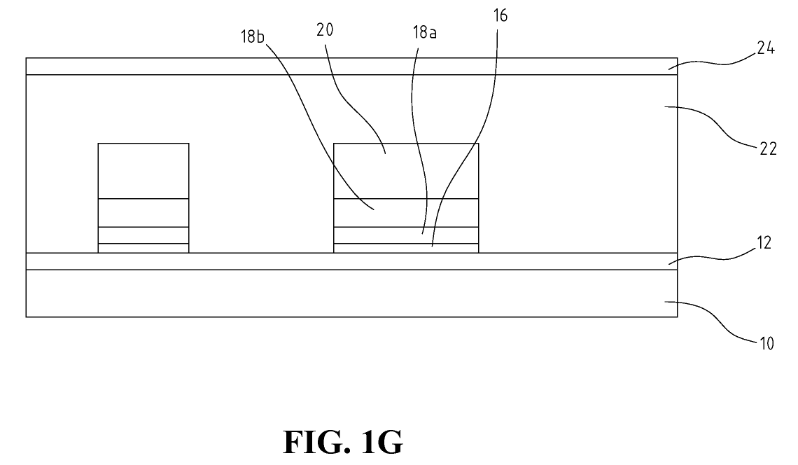

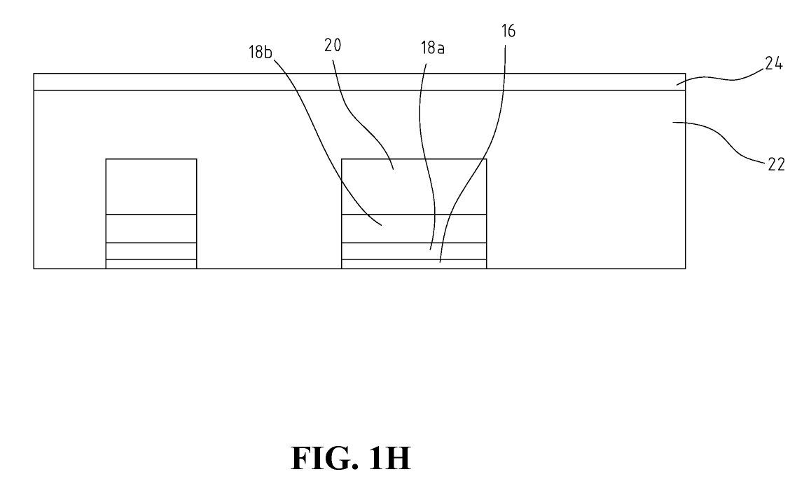

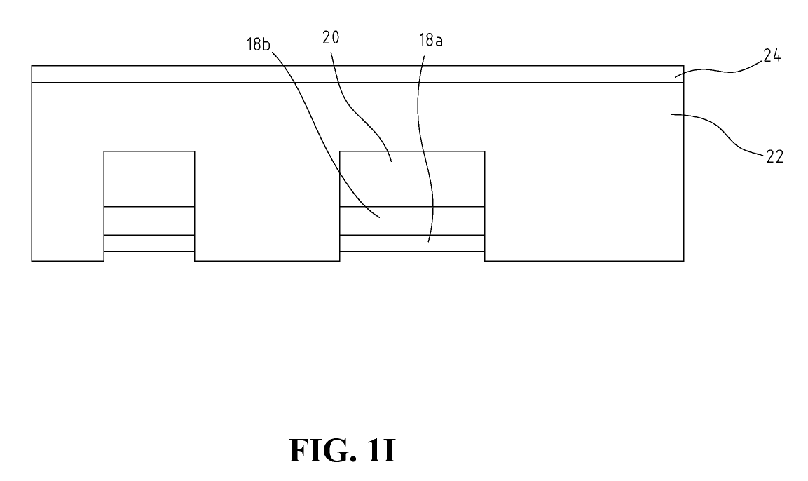

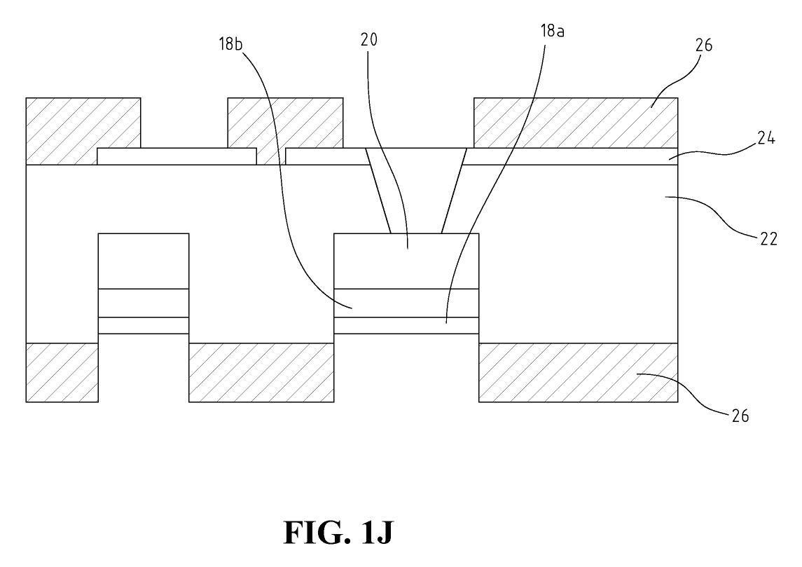

FIGS. 1A through 1J are schematic diagrams illustrating a method of selectively plating without plating lines according to a first embodiment of the present invention. Referring to FIG. 1D, a loading plate 10 can be made of a conductive material or an insulation material. A temporary conductive layer 12 is made of copper. A separating metal layer 16 is made of nickel. A plating protection layer 18a is made of gold. A plating protection layer 18b adjacent to a connection pad layer 20 is made of nickel. Because of the difference between the materials of the loading plate 10 and the temporary conductive layer 12, the loading plate 10 can be conveniently detached as shown in FIG. 1H. Because of the difference between the materials of the separating metal layer 16 and the temporary conductive layer 12, as shown in FIG. 1H, the separating metal layer 16 will not be destroyed when etching to remove the temporary conductive layer 12. Likewise, because of the difference between the materials of the separating metal layer 16 and the plating protection layer 18a, as shown in FIG. 1H, the separating metal layer 16 can be conveniently detached.

Generally, in the method of selectively plating without plating lines according to the present invention, in order to selectively plate nickel on a surface circuit layer, for protecting the surface circuit layer, a reverse process is employed, in which Au/Ni are plated first and Cu is then plated to form protection layers 18a and 18b, respectively, and therefore a connection pad layer 20 is plated as shown in FIG. 1D. After completing lamination and transfer process as shown in FIGS. 1F through 1G, a Cu/Ni etching process is performed for removing the temporary conductive layer 12, the separating metal layer 16, and finally exposing the gold-plated protection layer 18a, as shown in FIG. 1I. The method of the present invention differs from the conventional technologies, which require for plating gold to the protection layer at final. When executing the method, the detachable loading plate 10 and the temporary conductive layer 12 are adapted to provide a large range of plating current, so that even an independent pad which is not connected to any metal portion of the carrier board can also be used. The loading plate 10 and the temporary conductive layer 12 can be removed when the plate process is completed or it is not need to plate, thus achieving the objective of plating without plating lines.

Specifically, in the method of selectively plating without plating lines according to the present invention, at first the loading plate 10 having the temporary conductive layer 12 is provided. Then, as shown in FIG. 1D, the loading plate 10 and the temporary conductive layer 12 are used for supplying the plating current for selectively and sequentially plating the separating metal layer 16, the plating protection layers 18a and 18b, and the connection pad layer 20 on to the temporary conductive layer 12. Then, the loading plate 10 is further used for supplying current to form other circuit layers by a pressing lamination process as shown in FIGS. 1F though 1G And when the plate process is completed or it is not need to plate, the loading plate 10 and the temporary conductive layer 12 can be removed, for further completing for example the solder mask process, and thus achieving the objective of plating without plating lines, as shown in FIG. 1J.

Referring to FIG. 1B, a patterning photoresist layer 14 is formed for defining a position of the connection pad layer 20. Then, as shown in FIGS. 1C through 1D, with the loading plate 10 and the temporary conductive layer 12 supplying the plating current, the patterning photoresist layer 14 is accorded for selectively and sequentially plating the separating metal layer 16, the plating protection layers 18a and 18b, and the connection pad layer 20 on to the temporary conductive layer 12. Then, as shown in FIG. 1E, the patterning photoresist layer 14 is removed.

For further processing other portions of the carrier board, as shown in FIGS. 1F through 1G, a dielectric film 22 is laminated to the temporary conductive layer 12, as well as the separating metal layer 16, the plating protection layer 18a and 18b, the connection pad layer 20 formed thereon. For the purpose of allow the plating protection layer 18a and 18b signally communicating with outside, one or more drilling and filling plating processes are performed for configuring interlayer via hole as shown in FIG. 1J. After completing the filling plating process, the via hole can be adaptively finely processed by a grinding and polishing process, or a Ni/Au plating process. It should be noted that, the all of the foregoing plating processes can be supplied with plating current by the loading plate 10 and the temporary conductive layer 12, instead of any plating lines or temporary conductive lines.

As shown in FIGS. 1H through 1I, when there is no need to use the loading plate 10 and the temporary conductive layer 12 to transmit the plating current, the loading plate 10, the temporary conductive layer 12, and the separating metal layer 16 can be sequentially removed to expose a dielectric plastic film 22, and the plating protection layer 18a. Finally, after removing the loading plate 10, and the temporary conductive layer 12, a solder mask 26 is formed on the dielectric plastic film 22, as shown in FIG. 1J.

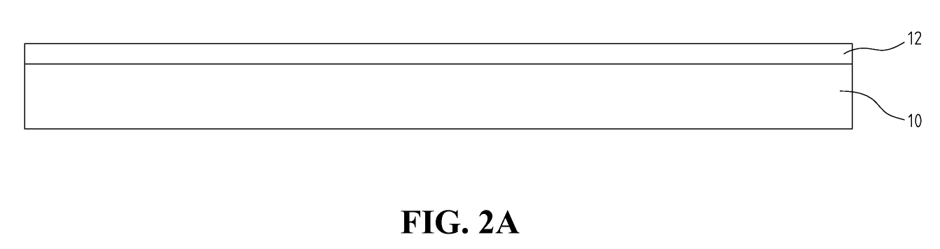

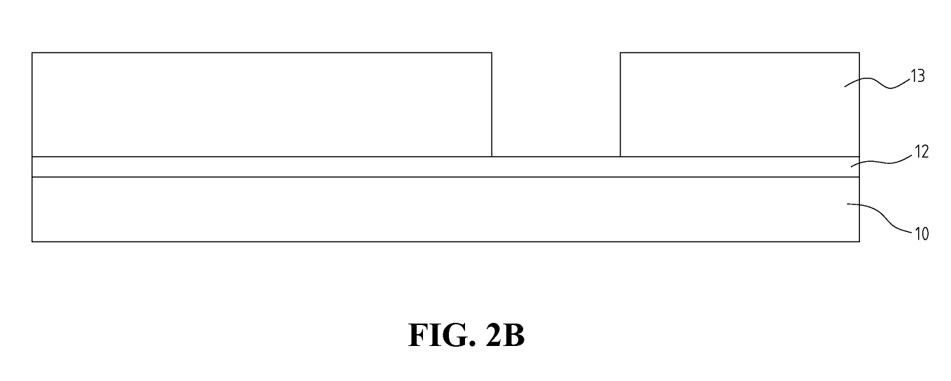

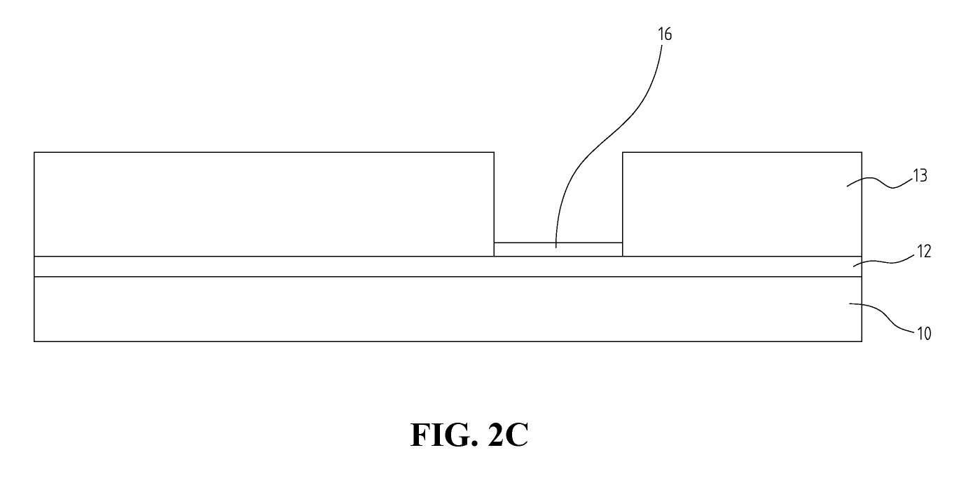

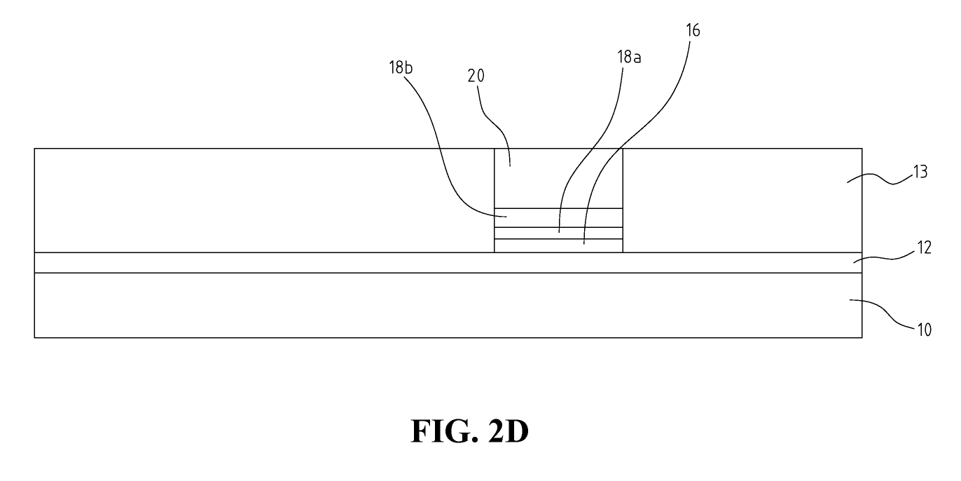

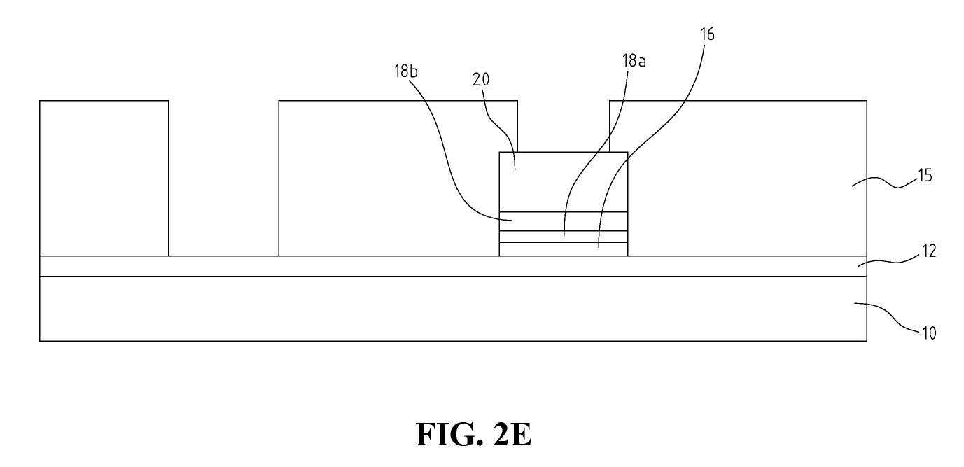

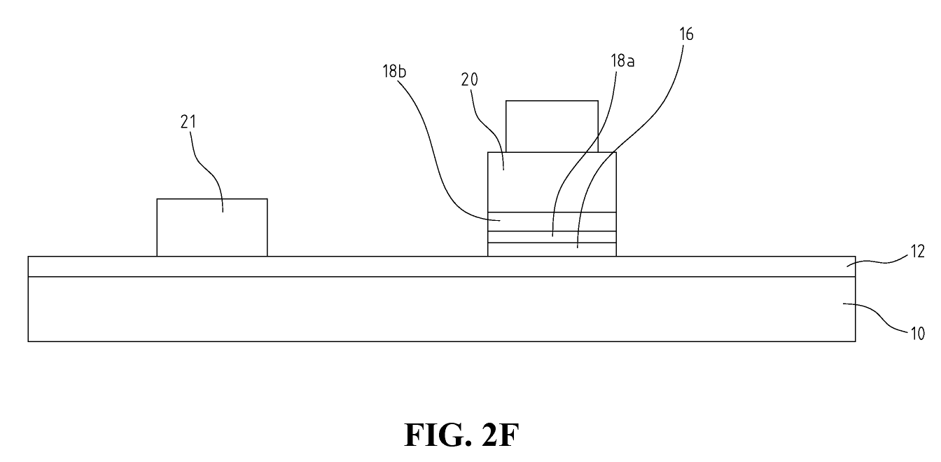

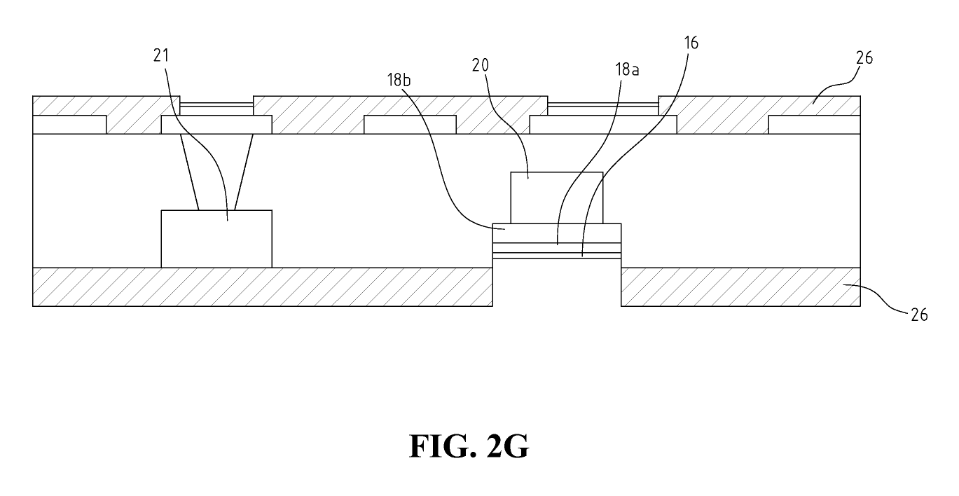

FIGS. 2A through 2G are schematic diagrams illustrating a method of selectively plating without plating lines according to a second embodiment of the present invention. As shown in FIGS. 2B though 2E, for the purpose of selectively plating Au/Ni in a same layer, two times of pattern transfer may be performed for preparing a connection pad layer 20 having plating protection layers 18a and 18b, and an unprotected connection pad layer 21, respectively, as shown in FIG. 2F.

Specifically, according to the current embodiment of the present invention, as shown in FIG. 2A, a loading plate 10 having a temporary conductive layer 12 configured thereon is provided. Then, as shown in FIG. 2B, a patterning photoresist layer 13 is formed on the temporary conductive layer 12 for defining a position of a connection pad layer 20. Then, as shown in FIGS. 2C through 2E, with the plating current supplied by the loading plate 10 and the temporary conductive layer 12, a separating metal layer 16, plating protection layers 18a and 18b, and the connection pad layer 20 are selectively and sequentially plated on to the temporary conductive layer 12, according to the patterning photoresist layer 13. Further, as shown in FIG. 2F, the patterning photoresist layer 13 is removed, and another patterning photoresist layer 15 is formed on the temporary conductive layer 12. Then the patterning photoresist layer 15 accorded for plating thus forming the connection pad layer 21, and finally the patterning photoresist layer 15 is also removed. In such a way, finally, after removing the loading plate 10, and the temporary conductive layer 12, a solder mask 26 is formed on the dielectric plastic film 22, as shown in FIG. 2G

Although the present invention has been described with reference to the preferred embodiments thereof, it is apparent to those skilled in the art that a variety of modifications and changes may be made without departing from the scope of the present invention which is intended to be defined by the appended claims.

What is claimed is:

1. A method of selectively plating without plating lines, comprising the steps of:
providing a loading plate having a metalized temporary conductive layer;
forming a patterning photoresist layer on the temporary conductive layer;
supplying a plating current with the loading plate and the temporary conductive layer, and according to the patterning photoresist layer, selectively and sequentially plating to form a separating metal layer, a plating protection layer, and a connection pad layer;
removing the patterning photoresist layer; and
laminating a dielectric plastic film onto the temporary conductive layer, as well as the separating metal layer, the plating protection layer, and the connection pad layer formed thereon,
wherein when there is no need for supplying the plating current with the loading plate and the temporary conductive layer, the loading plate, the temporary conductive layer and the separating metal layer are removed for exposing the dielectric plastic film and the plating protection layer.

2. The method according to claim 1, wherein the loading plate is made of a conductive material or an insulation material.

3. The method according to claim 1, wherein the temporary conductive layer is made of copper.

4. The method according to claim 1, wherein the separating metal layer is made of nickel.

5. The method according to claim 1, wherein the plating protection layer is made of gold.

6. The method according to claim 1, wherein the plating protection layer adjacent to the connection pad is made of nickel.

7. The method according to claim 1, further comprising the step of forming a solder mask layer on the exposed dielectric plastic film after removing the loading plate and the temporary conductive layer.
